(19) United States
(12) Patent Application Publication
(10) Pub. No.: US 2012/0238106 A1
(43) Pub. Date: Sep. 20, 2012

(54) COATING METHOD AND COATING APPARATUS

(75) Inventor: Chung-Bin CHUANG, Tainan City (TW)

(73) Assignee: TOKYO ELECTRON LIMITED, Tokyo (JP)

(21) Appl. No.: 13/421,321

(22) Filed: Mar. 15, 2012

(30) Foreign Application Priority Data
Mar. 18, 2011 (JP) 2011-61251

(51) Int. Cl. H01L 21/30; B05C 5/00; B05C 21/00

(52) U.S. Cl. 438/758; 118/52; 257/E21.211

(57) ABSTRACT

A coating method for coating a treatment liquid having a viscosity of 5 cp or less on a substrate includes rotating the substrate, increasing a rotation speed of the substrate while discharging the treatment liquid on the substrate from a nozzle, and repeating at least twice increasing and decreasing the rotation speed of the substrate while discharging the treatment liquid on the substrate from the nozzle.

### CROSS-REFERENCE TO RELATED APPLICATION

This application claims the benefit of Japanese Patent Application No. 2011-61251, filed on Mar. 18, 2011, in the Japan Patent Office, the disclosure of which is incorporated herein in its entirety by reference.

### TECHNICAL FIELD

The present disclosure relates to a coating method and a coating apparatus for coating a treatment liquid, e.g., a photoresist liquid, on a substrate to be processed such as a semiconductor wafer.

### BACKGROUND

When performing lithography in a manufacturing process of a semiconductor device, various processes, such as a resist coating process for coating a photoresist liquid on a surface of a semiconductor wafer (hereinafter, also referred to as “substrate” or “wafer”) to form a resist film, an exposure process for exposing the resist film to form a predetermined pattern and a developing process for developing the exposed resist film, are carried out, thereby forming a predetermined resist pattern.

In the resist coating process, a spin coating method is often used. In the spin coating method, a resist liquid is supplied from a nozzle toward a central portion of a wafer rotating at a high speed, the resist liquid spreads out on the wafer by a centrifugal force and the resist liquid is coated over the entire surface of the wafer.

There have been conventionally developed technologies to maintain uniform coating of the resist liquid and to reduce the consumption amount of the resist liquid. For example, there is a known method (hereinafter, “the first known method”) in which the rotation speed of a wafer is reduced to a standby rotation speed (or a stop state) during supplying of the resist liquid to the rotating wafer so that the extension of a so-called beard (the circumferentially-extending narrow flow of resist liquid radially distributed from the core of the resist liquid having a circular top-view shape) caused by centrifugal spreading of the resist liquid is temporarily stopped. In the first known method, it is possible to maintain a spreading pattern of the resist liquid because the resist liquid is collected in the central area of the wafer and then spread out at a low speed (see FIG. 8 showing a spreading pattern of a resist liquid during a decelerating step). Accordingly, it is possible to prevent the resist liquid from being significantly scattered from the peripheral edge portion of the wafer through the beard. Further, this allows reduction of the consumption amount of the resist liquid.

In addition, there is another known method (hereinafter, “the second known method”) in which a wafer rotates at a first speed prior to discharging a resist liquid and an acceleration is controlled to gradually increase and then gradually decrease so that the rotation speed of the wafer can be continuously changed from the first speed to a second speed higher than the first speed in a resist discharging step (namely, the line in a graph showing the rotation speed on a vertical axis and the time on a horizontal axis becomes an S-like curve).

In the first known method, the resist liquid needs to be maintained in a state where the resist does not reach the peripheral edge portion of the wafer for a predetermined period of time. Therefore, if the viscosity of the resist liquid is low (e.g., 5 cp or less), the resist liquid dries prior to being coated over the entire surface of the wafer. This causes the problem that a film cannot be coated uniformly. Moreover, the first known method fails to adapt itself to a so-called pre-wetting treatment in which a solvent such as a thinner or the like is applied on a wafer in advance.

In the second known method, it is possible to reliably and uniformly coat the resist liquid, thereby reducing the consumption amount of the resist liquid. However, the demand for the reduction of the consumption amount of the resist liquid grows higher as semiconductor circuits become finer. Further, in the manufacturing process, the reduction of the consumption amount of the resist liquid by only a small amount of, e.g., 0.1 ml greatly assists in saving manufacturing cost.

### SUMMARY

The present disclosure provides a coating method and a coating apparatus which allows reduction of the consumption amount of a treatment liquid and uniform distribution of the treatment liquid over an entire surface of a substrate, even when the viscosity of the treatment liquid is relatively low.

According to one aspect of the present disclosure, there is provided a coating method for coating a treatment liquid having a viscosity of 5 cp or less on a substrate, including: discharging the treatment liquid from a nozzle on a central portion of the substrate while the substrate is rotated at a first speed and then forming a coated region on a surface of the substrate with the treatment liquid by increasing a rotation speed of the substrate from the first speed to a second speed; enlarging the coated region by increasing the rotation speed of the substrate from the second speed to a third speed; uniformly distributing the treatment liquid by decreasing the rotation speed of the substrate from the third speed to a fourth speed; enlarging the coated region to reach a peripheral edge portion of the substrate by increasing the rotation speed of the substrate from the fourth speed to a fifth speed higher than the second speed; and stopping discharging the treatment liquid from the nozzle and uniformly distributing the treatment liquid by decreasing the rotation speed of the substrate from the fifth speed to a sixth speed.

According to another aspect of the present disclosure, there is provided a coating method for coating a treatment liquid having a viscosity of 5 cp or less on a substrate, including: rotating the substrate; and increasing a rotation speed of the substrate from a first speed to a second speed higher than the first speed while discharging the treatment liquid on the substrate from a nozzle, then decreasing the rotation speed of the substrate to a third speed lower than the second speed while discharging the treatment liquid on the substrate from the nozzle, then increasing the rotation speed of the substrate to a fourth speed higher than the third speed while discharging the treatment liquid on the substrate from the nozzle and then decreasing the rotation speed of the substrate to a fifth speed lower than the fourth speed while discharging the treatment liquid on the substrate from the nozzle.

According to a further aspect of the present disclosure, there is provided a coating method for coating a treatment liquid having a viscosity of 5 cp or less on a substrate, including: rotating the substrate; increasing a rotation speed of the substrate while discharging the treatment liquid on the substrate from a nozzle; and repeating at least twice increasing and decreasing the rotation speed of the substrate while discharging the treatment liquid on the substrate from the nozzle.

According to a still further aspect of the present disclosure, there is provided a coating apparatus for coating a treatment liquid on a substrate, including: a rotating holder unit configured to hold and rotate the substrate; a nozzle configured to discharge the treatment liquid on the substrate; and a control unit configured to control operations of the rotating holder unit and the nozzle to perform the coating method of any one of the aspects stated above.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a graph representing substrate rotation speed in each step of a conventional coating method.

FIG. 2 is a vertical sectional view showing a schematic structure of a coating apparatus for performing a coating method according to an embodiment of the present disclosure.

FIG. 3 is a horizontal sectional view showing the schematic structure of the coating apparatus for performing the coating method according to the embodiment of the present disclosure.

FIG. 4 is a flowchart illustrating steps of the coating method according to the embodiment of the present disclosure.

FIG. 5 is a graph representing wafer rotation speed in each step of the coating method according to the embodiment of the present disclosure.

FIGS. 6A through 6E are explanatory views showing the coating state on the wafer surface in each step of the coating method according to the embodiment of the present disclosure, and FIG. 6F is an explanatory view showing a coating defect.

FIG. 7 shows thickness measurement results of the resist films formed by coating the resist liquid on the wafers through the use of the coating method according to the embodiment of the present disclosure.

FIG. 8 is an explanatory view showing a spreading pattern of the resist liquid in a decelerating step of a conventional coating method.

FIG. 9 is an explanatory view showing a spreading pattern of the resist liquid in a decelerating step according to the embodiment of the present disclosure.

### DETAILED DESCRIPTION

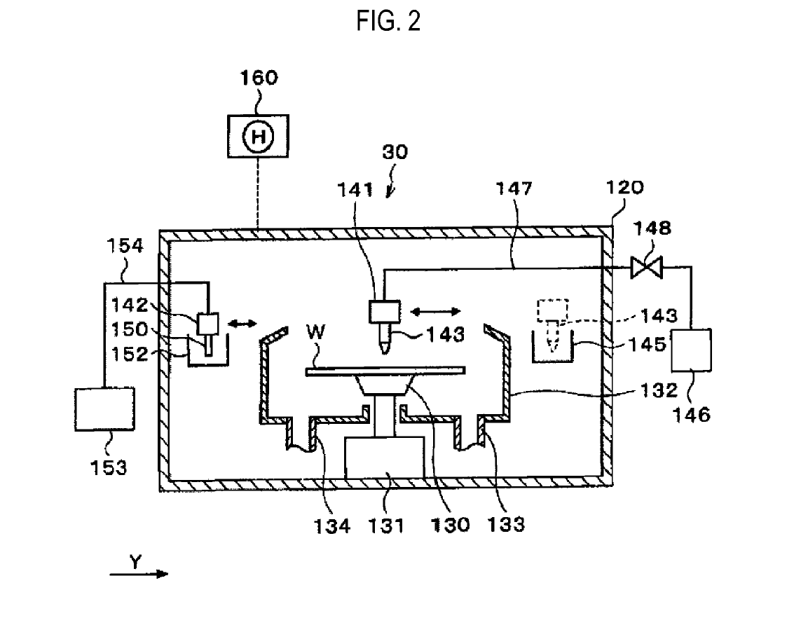

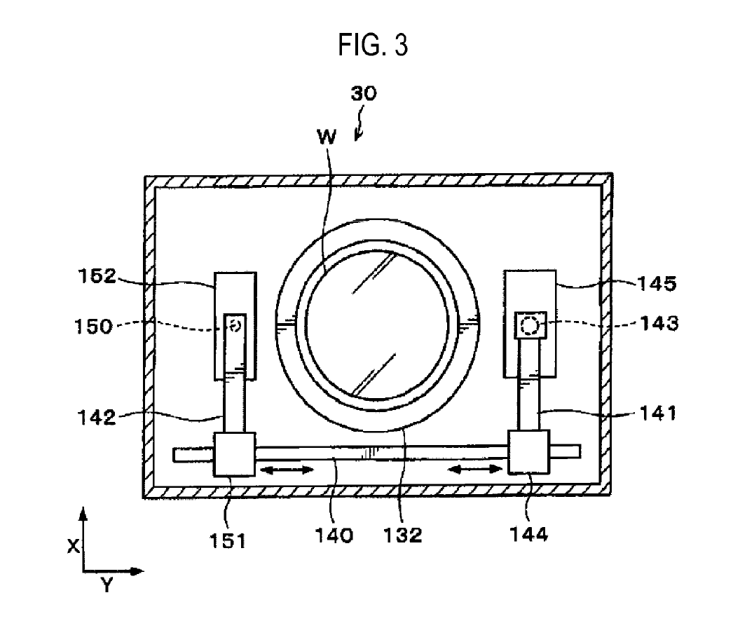

An embodiment of the present disclosure will now be described in detail with reference to the drawings. FIG. 2 is a vertical sectional view showing a schematic structure of a coating apparatus 30 for performing a coating method according to an embodiment of the present disclosure. FIG. 3 is a horizontal sectional view showing the schematic structure of the coating apparatus 30.

As shown in FIG. 2, the coating apparatus 30 includes a housing 120 and a spin chuck 130 as a rotating holder unit provided in a central region within the housing 120 to hold and rotate a wafer W. The spin chuck 130 includes a horizontal upper surface having suction holes (not shown) capable of suctioning a substrate such as the wafer W or the like. Using the suctioning force of the suction holes, the spin chuck 130 can suction and hold the wafer W thereon.

A chuck drive mechanism 131 is connected to the spin chuck 130. The chuck drive mechanism 131 is provided with a unit such as an electric motor. The spin chuck 130 can be rotated at a predetermined speed by the chuck drive mechanism 131. The chuck drive mechanism 131 includes an up-down drive unit (not shown) such as a cylinder or the like and can move the spin chuck 130 up and down. The rotation speed of the spin chuck 130 is controlled by a control unit 160 to be described later.

A cup-shaped body 132 is provided around the spin chuck 130 to receive and collect the liquid scattered from the wafer W. A discharge pipe 133 for draining the collected liquid and an exhaust pipe 134 for discharging a gas existing from within the cup-shaped body 132 are connected to the bottom surface of the cup-shaped body 132.

As shown in FIG. 3, a track shaft 140 extending in the Y-axis direction (in the left-right direction in FIG. 3) is provided at the backward side of the cup-shaped body 132 in the X-axis direction (at the lower side in FIG. 3). The track shaft 140 extends from the backwardly outer side (the left side in FIG. 3) to the forwardly outer side (the right side in FIG. 3) in the Y-axis direction. A first arm 141 (at the forward side in the Y-axis direction) and a second arm 142 (at the backward side in the Y-axis direction) are provided on the track shaft 140 to move along the track shaft 140.

As shown in FIGS. 2 and 3, a first nozzle 143 is supported near the tip end of the first arm 141 and can discharge a treatment liquid such as a photoresist liquid. The first arm 141 is freely moved along the track shaft 140 by the operation of a nozzle drive unit 144 shown in FIG. 3. Accordingly, the first nozzle 143 is controlled to move from a standby unit 145 provided at the forwardly outer side (the right side in FIG. 3) of the cup-shaped body 132 in the Y-axis direction to the upper side in the X-axis direction of the central portion of the wafer W positioned within the cup-shaped body 132 and to move along the radial direction of the wafer W on the surface of the wafer W. In addition, the first arm 141 is freely moved up or down by the operation of the nozzle drive unit 144 to adjust the height of the first nozzle 143. In the present embodiment, the first arm 141 and the nozzle drive unit 144 constitute a “treatment liquid nozzle moving means.”

The first nozzle 143 is connected to a supply pipe 147 in communication with a treatment liquid source 146 shown in FIG. 2. The treatment liquid source 146 contains a treatment liquid, such as a resist liquid, for forming a resist film. In addition, a valve 148 is provided in the supply pipe 147. The treatment liquid is discharged or shut off by opening or closing the valve 148.

A second nozzle 150 is supported near the tip end of the second arm 142 and can discharge a solvent for the treatment liquid. The second arm 142 is freely moved along the track shaft 140 by the operation of a nozzle drive unit 151 shown in FIG. 3. The second nozzle 150 is controlled to move from a standby unit 152 provided at the backwardly outer side (the left side in FIG. 3) of the cup-shaped body 132 in the Y-axis direction to the upper side in the X-axis direction of the central portion of the wafer W positioned within the cup-shaped body 132. In addition, the second arm 142 is freely moved up or down by the operation of the nozzle drive unit 151 to adjust the height of the second nozzle 150. In the present embodiment, the second arm 142 and the nozzle drive unit 151 constitute a “solvent nozzle moving means.”

The second nozzle 150 is connected to a supply pipe 154 in communication with a solvent source 153 shown in FIG. 2. While the first nozzle 143 for discharging the treatment liquid and the second nozzle 150 for discharging the solvent are supported by different arms in the structure described above, they may be supported by a single arm. The movement of the first nozzle 143 and the second nozzle 150 and the discharge time are controlled by controlling the movement of the first arm 141 and the second arm 142.

A control unit 160 controls the operation of the drive system, such as the rotating operation of the spin chuck 130, the drive operation of the nozzle drive unit 144 for moving the first nozzle 143, the opening/closing operation of the valve 148 for allowing or stopping the treatment liquid discharge of the first nozzle 143 and the drive operation of the nozzle drive unit 151 for moving the second nozzle 150. The control unit 160 is formed of a computer including a CPU and a memory. The control unit 160 controls the coating apparatus 30 to perform a coating process by executing programs stored in the memory. The programs for controlling the coating apparatus 30 to perform the coating process are stored in a computer-readable recording medium H and can be installed on the control unit 160 from the recording medium H.

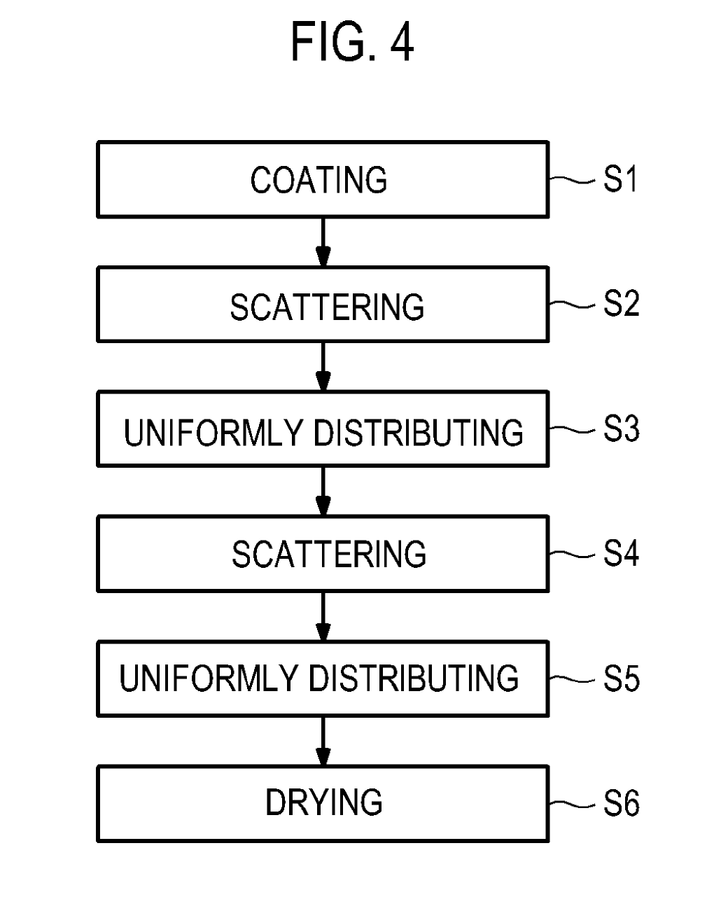

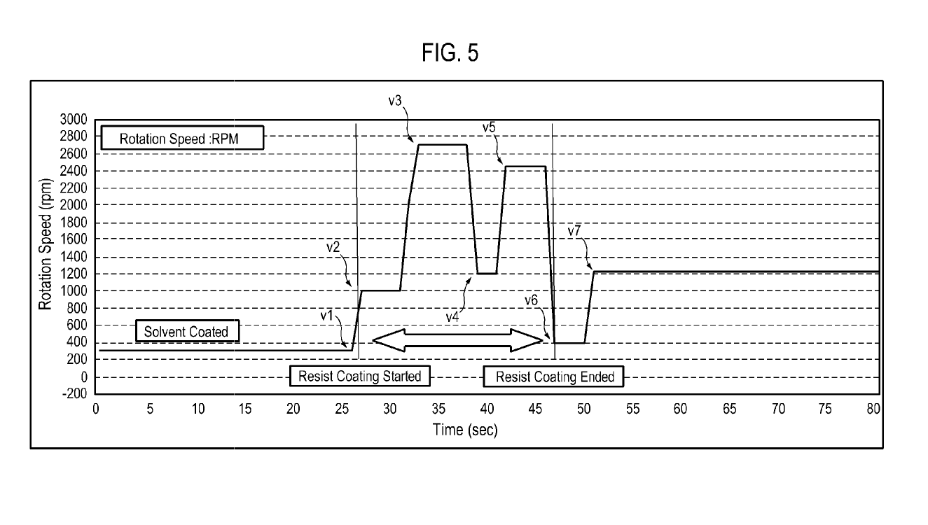

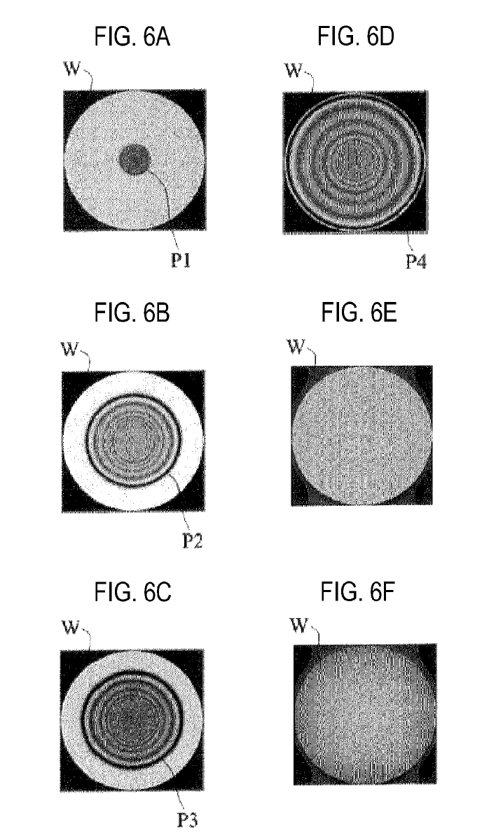

FIG. 4 is a flowchart illustrating the steps of the coating method according to the embodiment of the present disclosure. FIG. 5 is a graph representing the rotation speeds of the wafer W in the coating method according to the embodiment of the present disclosure. FIGS. 6A through 6E are explanatory views showing the coating state on the surface of the wafer W in each step of the coating method according to the embodiment of the present disclosure. FIG. 6F is an explanatory view showing the coating state with a defect. The steps of the coating method according to the embodiment of the present disclosure will now be described with reference to FIGS. 4, 5 and 6.

First, the wafer W is loaded into the coating apparatus 30 and is suctioned and held on the spin chuck 130 shown in FIG. 2. Then, the second arm 142 causes the second nozzle 150 positioned on the standby unit 152 to move to the upper side in the x-axis direction of the central portion of the wafer W. Thereafter, while not rotating the wafer W, a predetermined amount of solvent is discharged from the second nozzle 150 onto the central portion of the wafer W. Next, as shown in FIG. 5, the spin chuck 130 causes the wafer W to rotate at a first speed v1 of, e.g., about 300 rpm, thereby spreading out the solvent on the wafer W and coating the solvent over the entire surface of the wafer W. The second arm 142 returns the second nozzle 150 back to the standby unit 152.

Thereafter, the first arm 141 causes the first nozzle 143 positioned on the standby unit 145 to move to the upper side in the x-axis direction of the central portion of the wafer W. Then, the valve 148 is opened to cause the first nozzle 143 to discharge a treatment liquid having a relatively low viscosity (of 5 cp or less), e.g., a resist liquid, on the central portion of the wafer W. At this time, as shown in FIG. 5, the rotation speed of the wafer W is increased from the first speed v1 to a second speed v2 of, e.g., about 1000 rpm. Thus, the resist liquid supplied on the central portion of the wafer W is spread out by centrifugal force. As shown in FIG. 6A, a circular coated region P1 is formed on the surface of the wafer W (step S1 in FIG. 4).

Subsequently, as shown in FIG. 5, the rotation speed of the wafer W is increased from the second speed v2 to a third speed v3 of, e.g., about 2700 rpm. Thus, the resist liquid is affected by centrifugal force again and, as shown in FIG. 6B, is spread out on the surface of the wafer W to form a circular coated region P2 greater in size than the circular coated region P1 (step S2 in FIG. 4).

Thereafter, as shown in FIG. 5, the rotation speed of the wafer W is decreased from the third speed v3 to a fourth speed v4 of, e.g., about 1200 rpm. At this time, the coverage rate (coating surface ratio) of the resist liquid on the surface of the wafer W is increased by the deceleration. As shown in FIG. 6C, a circular coated region P3 is formed on the surface of the wafer W (step S3 in FIG. 4). FIG. 9 is a sectional side view seen from the side of the wafer, showing a spreading pattern of the resist liquid at this time.

Then, as shown in FIG. 5, the rotation speed of the wafer W is increased from the fourth speed v4 to a fifth speed v5 of, e.g., about 2450 rpm. Thus, the resist liquid is affected by centrifugal force again and is spread out to the peripheral edge portion of the wafer W. As shown in FIG. 6D, a circular coated region P4 is formed on the surface of the wafer W (step S4 in FIG. 4).

Subsequently, as shown in FIG. 5, the rotation speed of the wafer W is decreased from the fifth speed v5 to a sixth speed v6 of, e.g., about 400 rpm, and the discharge of the resist liquid from the first nozzle 143 to the central portion of the wafer W is stopped. At this time, as shown in FIG. 6E, the resist liquid is completely coated over the entire surface of the wafer W by the deceleration. Thus, the resist liquid is uniformly coated on the entire surface of the wafer W (step S5 in FIG. 4). In the present embodiment, the resist liquid is used as a treatment liquid having a viscosity of 5 cp or less. In a state that the resist liquid is discharged from the nozzle, the resist liquid spreads out to the peripheral edge portion of the wafer W when the revolution number is increased for the final time.

Thereafter, as shown in FIG. 5, the rotation speed of the wafer W is increased from the sixth speed v6 to a seventh speed v7 of, e.g., about 1200 rpm. The thickness of the resist film is decided by the magnitude of the seventh speed v7. While continuously rotating the wafer W for a predetermined time, the resist film on the surface of the wafer W is dried (step S6 in FIG. 4).

After the resist film is dried, the rotation of the wafer W is stopped and the wafer W is unloaded from the spin chuck 130, thereby finishing the series of steps of the coating method according to the embodiment of the present disclosure.

In the process described above, the process time in the respective steps S1 through S5 is approximately 0.1 to 1.5 seconds. The rotation speeds v3 and v5 of the wafer W is higher than the rotation speeds v2 and v4, respectively. The difference in the rotation speeds is equal to or greater than 1000 rpm.

The present disclosure will now be described in detail in conjunction with Examples and Comparative Examples. However, the present disclosure is not limited to the Examples set forth below.

### EXAMPLE 1

The coating method of the present disclosure was performed by the coating apparatus 30 shown in FIG. 2. In the present Example, a solvent (product name: OK73) produced by Tokyo Ohka Kogyo Co., Ltd., Japan, and a resist liquid (product name: SAIL-X145) produced by Shin-Etsu Chemical Co., Ltd., Japan were used. The viscosity of the resist liquid was set as about 2 cp, the amount of the resist liquid used was set as 0.50 ml to 1.00 ml, the process time in the steps S1 through S5 was set as 0.1 to 1.5 seconds, the rotation speeds v2 and v4 in the steps S1 and S3 were set as 1000 rpm, and the rotation speeds v3 and v5 in the steps S2 and S4 were set as 2000 rpm. It was checked whether the resist liquid used in each case was uniformly coated on the entire surface of the wafer W. If the coating was uniform, recording was made to read “OK.” If the coating was uneven or defective (as shown in FIG. 6F), recording was made to read “NG.”

### EXAMPLE 2

The same conditions as in Example 1 were used except that the rotation speeds v3 and v5 in the steps S2 and S4 were set as 3000 rpm. It was checked whether the resist liquid used in each case was uniformly coated on the entire surface of the wafer W. If the coating was uniform, recording was made to read “OK.” If the coating was uneven or defective, recording was made to read “NG.”

### EXAMPLE 3

The same conditions as in Example 1 were used except that the rotation speeds v3 and v5 in the steps S2 and S4 were set as 4000 rpm. It was checked whether the resist liquid used in each case was uniformly coated on the entire surface of the wafer W. If the coating was uniform, recording was made to read “OK.” If the coating was uneven or defective, recording was made to read “NG.”

The test results obtained in Examples 1 through 3 are shown in Table 1.

TABLE 1

| | v3, v5 | Amount of Resist Liquid Used (ml) | | | | | | | | | | |
|---|---|---|---|---|---|---|---|---|---|---|---|---|
| | (rpm) | 0.5 | 0.55 | 0.6 | 0.65 | 0.7 | 0.75 | 0.8 | 0.85 | 0.9 | 0.95 | 1 |
| Ex. 1 | 2000 | NG | NG | OK | OK | OK | OK | OK | OK | OK | OK | OK |
| Ex. 2 | 3000 | NG | OK | OK | OK | OK | OK | OK | OK | OK | OK | OK |
| Ex. 3 | 4000 | NG | OK | OK | OK | OK | OK | OK | OK | OK | OK | OK |

As can be noted from Table 1, when the rotation speeds v3 and v5 in the steps S2 and S4 are set as 2000 rpm, it is possible to uniformly coat the resist liquid on the entire surface of the wafer W if the amount of the resist liquid used is 0.60 ml or more. When the rotation speeds v3 and v5 in the steps S2 and S4 are set as 3000 rpm or 4000 rpm, it is possible to uniformly coat the resist liquid on the entire surface of the wafer W if the amount of the resist liquid used is 0.55 ml or more.

### COMPARATIVE EXAMPLE 1

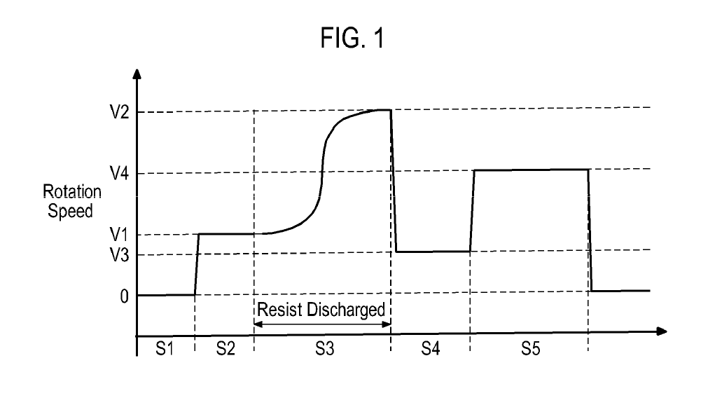

The second known method described in the BACKGROUND section was performed by the coating apparatus 30 shown in FIG. 2. A solvent (product name: OK73) produced by Tokyo Ohka Kogyo Co., Ltd., Japan, and a resist liquid (product name: SAIL-X145) produced by Shin-Etsu Chemical Co., Ltd., Japan were used. The viscosity of the resist liquid was set as about 2 cp and the amount of the resist liquid used was set as 0.50 ml to 1.00 ml. As shown in FIG. 1, the rotation speed of the wafer W was increased from v1 to v2 in an S-like pattern. The rotation speed v1 was set as 500 rpm and the rotation speed v2 was set as 2000 rpm. It was checked whether the resist liquid used in each case was uniformly coated on the entire surface of the wafer W. If the coating was uniform, recording was made to read “OK.” If the coating was uneven or defective, recording was made to read “NG.”

### COMPARATIVE EXAMPLE 2

The same conditions as in Comparative Example 1 were used except that the rotation speeds v2 was set as 3000 rpm. It was checked whether the resist liquid used in each case was uniformly coated on the entire surface of the wafer W. If the coating was uniform, recording was made to read “OK.” If the coating was uneven or defective, recording was made to read “NG.”

### COMPARATIVE EXAMPLE 3

The same conditions as in Comparative Example 1 were used except that the rotation speeds v2 was set as 4000 rpm. It was checked whether the resist liquid used in each case was uniformly coated on the entire surface of the wafer W. If the coating was uniform, recording was made to read “OK.” If the coating was uneven or defective, recording was made to read “NG.”

The test results obtained in Comparative Examples 1 through 3 are shown in Table 2.

TABLE 2

| | v2 | Amount of Resist Liquid Used (ml) | | | | | | | | | | |
|---|---|---|---|---|---|---|---|---|---|---|---|---|
| | (rpm) | 0.5 | 0.55 | 0.6 | 0.65 | 0.7 | 0.75 | 0.8 | 0.85 | 0.9 | 0.95 | 1 |
| Comp. | 2000 | NG | NG | NG | NG | OK | OK | OK | OK | OK | OK | OK |
| Ex. 1 | | | | | | | | | | | | |
| Comp. | 3000 | NG | NG | NG | OK | OK | OK | OK | OK | OK | OK | OK |
| Ex. 2 | | | | | | | | | | | | |
| Comp. | 4000 | NG | NG | OK | OK | OK | OK | OK | OK | OK | OK | OK |
| Ex. 3 | | | | | | | | | | | | |

As can be noted from Table 2, when the rotation speed v2 is set as 2000 rpm, it is impossible using the first known method described in the BACKGROUND section to uniformly coat the resist liquid on the entire surface of the wafer W unless the amount of the resist liquid used is 0.70 ml or more. When the rotation speed v2 is set as 3000 rpm, it is impossible to uniformly coat the resist liquid on the entire surface of the wafer W unless the amount of the resist liquid used is 0.65 ml or more. When the rotation speed v2 is set as 4000 rpm, it is impossible to uniformly coat the resist liquid on the entire surface of the wafer W unless the amount of the resist liquid used is 0.60 ml or more.

As is apparent from the comparison of the test results shown in Tables 1 and 2, when the highest rotation speed of the wafer W is 2000 rpm, the coating method of the present disclosure can save the use amount of the resist liquid by about 0.1 ml compared with the coating method of the first known method described in the BACKGROUND section. When the highest rotation speed of the wafer W is 3000 rpm, the coating method of the present disclosure can save the use amount of the resist liquid by about 0.1 ml. When the highest rotation speed of the wafer W is 4000 rpm, the coating method of the present disclosure can save the use amount of the resist liquid by about 0.05 ml.

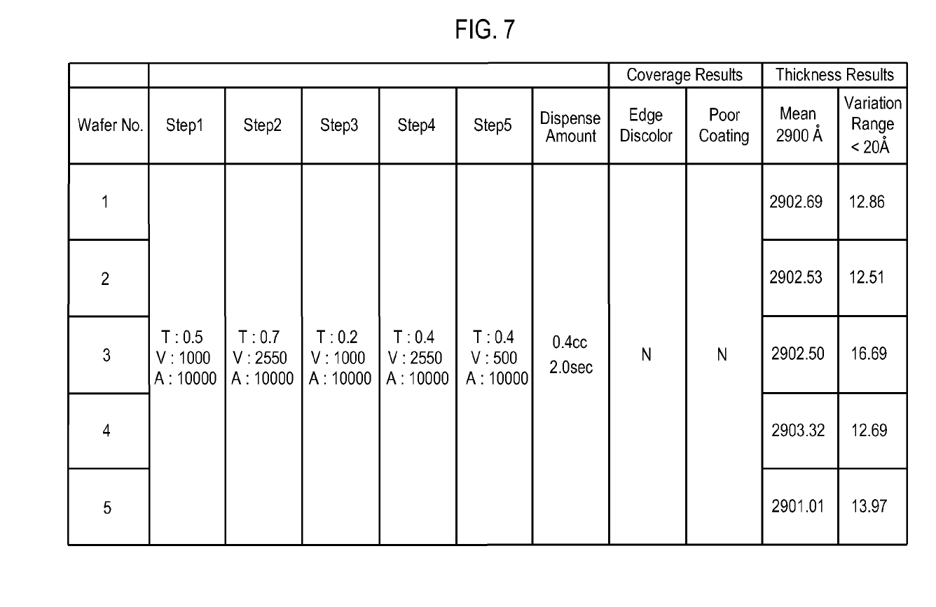

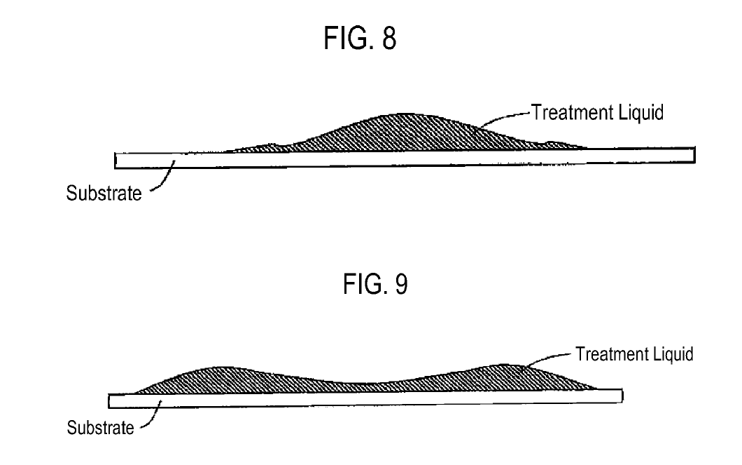

Next, tests were conducted to determine whether the thickness of the resist films coated by the coating method of the present disclosure is uniform. FIG. 7 shows the thickness measurement results of the resist films coated on the wafers W by the coating method of the present disclosure. As shown in FIG. 7, a resist liquid was coated on five wafers W of Nos. (Wafer Nos.) 1 through 5 by the coating method of the present disclosure. In the steps 1 through 5 shown in FIG. 7, T denotes the duration (sec) of the respective steps, V stands for the rotation speeds (rpm) of the wafers W, and A stands for the acceleration (xg) of the rotation speed. The viscosity of the resist liquid coated was about 1.2 cp, the discharge amount was as small as 0.4 cc, and the discharge time was 2 seconds in total.

After finishing the coating, it was checked whether there existed an abnormality in the color of the peripheral edges of the respective wafers W or a defect in the coating. Thereafter, 49 measurement points were set on the coating surface of each of the wafers W, and the thickness of the resist films was measured at the respective measurement points. The mean of the thickness at the respective measurement points and the variation range of the thickness were calculated. The results of measurement show that an abnormality in the color of the peripheral edges of the respective wafers W or a defect in the coating was not found. The mean of the thickness measured at the measurement points was about 2900 Å and the variation range of the thickness was 20 Å or less. It can be appreciated that resist films were very uniformly formed on the surfaces of the wafers W.

As is apparent from the above, the coating method of the present disclosure makes it possible to uniformly coat the resist liquid on the entire surface of the wafer W even if the amount of the resist liquid is quite small.

While the embodiment and examples of the present disclosure have been described above with reference to the drawings, the present disclosure is not limited thereto. For example, although the coating is performed with respect to a semiconductor wafer in the embodiment described above, the present disclosure may be applied to a substrate other than a wafer, e.g., an FPD (Flat Panel Display) substrate, or other substrates. Moreover, although the resist liquid is used as the treatment liquid having a viscosity of 5 cp or less in the embodiment described above, it may be possible to use a coating liquid other than the resist liquid, e.g., a coating liquid for forming an anti-reflection film, an SOG (Spin-On-Glass) film or an SOD (Spin-On-Dielectric) film, or a coating liquid for forming an anti-reflection film or a immersion exposure protection film. Although the speed difference between the rotation speed v3 or v5 and the rotation speed v2 or v4 of the wafer W is set as 1000 rpm or more in the embodiment described above, the speed difference may be less than 1000 rpm as far as it is possible to uniformly distribute the resist liquid by the deceleration during speed reduction. Although the highest rotation speed of the wafer W is set to fall within a range of 2000 to 4000 rpm in the embodiment described above, the highest rotation speed may be properly set in conformity with the viscosity of the resist liquid coated and the structure and performance of the coating apparatus used. Although the process time in each step is set to fall within a range of 0.1 to 1.5 seconds in the embodiment described above, the process time may be properly set in conformity with the volatility of the liquid coated.

The present disclosure can be applied to a coating method and a coating apparatus for coating a treatment liquid such as a photoresist liquid on a substrate to be processed such as a semiconductor wafer.

With the present disclosure, it is possible to provide a coating method and a coating apparatus being capable of saving an amount of a treatment liquid and uniformly coating the treatment liquid on an entire surface of a substrate even when the treatment liquid having a relatively low viscosity is used.

While one embodiment has been described, this embodiment has been presented by way of example only, and is not intended to limit the scope of the disclosures. Indeed, the novel method and apparatus described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A coating method for coating a treatment liquid having a viscosity of 5 cp or less on a substrate, comprising:
discharging the treatment liquid from a nozzle on a central portion of the substrate while the substrate is rotated at a first speed and then forming a coated region on a surface of the substrate with the treatment liquid by increasing a rotation speed of the substrate from the first speed to a second speed;
enlarging the coated region by increasing the rotation speed of the substrate from the second speed to a third speed;
uniformly distributing the treatment liquid by decreasing the rotation speed of the substrate from the third speed to a fourth speed;
enlarging the coated region to reach a peripheral edge portion of the substrate by increasing the rotation speed of the substrate from the fourth speed to a fifth speed higher than the second speed; and
stopping discharging the treatment liquid from the nozzle and uniformly distributing the treatment liquid by decreasing the rotation speed of the substrate from the fifth speed to a sixth speed.

2. A coating method for coating a treatment liquid having a viscosity of 5 cp or less on a substrate, comprising:
rotating the substrate; and
increasing a rotation speed of the substrate from a first speed to a second speed higher than the first speed while discharging the treatment liquid on the substrate from a nozzle, then decreasing the rotation speed of the substrate to a third speed lower than the second speed while discharging the treatment liquid on the substrate from the nozzle, then increasing the rotation speed of the substrate to a fourth speed higher than the third speed while discharging the treatment liquid on the substrate from the nozzle and then decreasing the rotation speed of the substrate to a fifth speed lower than the fourth speed while discharging the treatment liquid on the substrate from the nozzle.

3. The method of claim 1, further comprising:
increasing the rotation speed of the substrate from the sixth speed to a seventh speed to scatter away extra treatment liquid and dry the treatment liquid remaining on the surface of the substrate.

4. The method of claim 3, wherein the treatment liquid is a resist liquid.

5. The method of claim 4, wherein the third speed differs from the second speed and the fourth speed by 1000 rpm or more, and the fifth speed differs from the second speed and the fourth speed by 1000 rpm or more.

6. The method of claim 5, wherein the third speed and the fifth speed are in a range of 2000 to 4000 rpm.

7. The method of claim 6, wherein a process time in each step is 0.1 to 1.5 seconds.

8. A coating method for coating a treatment liquid having a viscosity of 5 cp or less on a substrate, comprising:
rotating the substrate;
increasing a rotation speed of the substrate while discharging the treatment liquid on the substrate from a nozzle; and
repeating at least twice increasing and decreasing the rotation speed of the substrate while discharging the treatment liquid on the substrate from the nozzle.

9. The method of claim 8, further comprising:
coating a solvent for the treatment liquid on the substrate prior to discharging the treatment liquid on the substrate from the nozzle.

10. The method of claim 8, wherein the viscosity of the treatment liquid is 2 cp or less.

11. A coating apparatus for coating a treatment liquid on a substrate, comprising:
a rotating holder unit configured to hold and rotate the substrate;
a nozzle configured to discharge the treatment liquid on the substrate; and
a control unit configured to control operations of the rotating holder unit and the nozzle to perform the coating method of claim 1.
